(19) United States
(12) Patent Application Publication
(10) Pub. No.: US 2012/0187895 A1
(43) Pub. Date: Jul. 26, 2012

(54) ELECTRONIC APPARATUS AND INFORMATION INPUT MODULE USING SOLAR CELL

(75) Inventors: KUAN-HONG HSIEH, Tu-Cheng (TW); HAN-CHE WANG, Tu-Cheng (TW); CHIU-HSIUNG LIN, Tu-Cheng (TW); PO-FU CHENG, Tu-Cheng (TW); BIN-GANG DUAN, Shenzhen City (CN); MING-CHOU CHANG, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD, Shenzhen (CN)

(21) Appl. No.: 13/207,413

(22) Filed: Aug. 10, 2011

(30) Foreign Application Priority Data
Jan. 25, 2011 (CN) 201110027224.8

(51) Int. Cl. H01M 10/46; H01L 31/042

(52) U.S. Cl. 320/101; 136/244

(57) ABSTRACT

A solar power module includes a solar power generation layer, a first electrode layer, and a second electrode layer. The solar power generation receives photons and includes a number of solar power generation units. The first electrode layer is connected with the solar power generation layer. The second electrode layer is connected with the solar power generation layer, and includes a number of conductive electrodes. Each conductive electrode is connected with one of the solar power generation unit. The conductive electrode transmits an electrical parameter variation of the corresponding solar power generation unit to a detection unit to transform the electrical parameter variation into corresponding input command.

BACKGROUND

1. Technical Field

The present disclosure relates to an electronic apparatus, and particularly, to an electronic apparatus using solar cells.

2. Description of Related Art

A solar cell can convert sunlight directly into electricity by the photovoltaic effect. Generally, the solar cell is made of semiconducting materials, such as silicon, for absorbing photons in sunlight and releasing electrons. A solar module consists of many jointly connected solar cells to supply electricity at a certain voltage, and multiple solar modules can be wired together to form a solar array. In general, the larger the area of the solar module or the solar array, the more electricity the solar module or the solar array will produce.

Some electronic devices include a solar module for supplying extra power in addition to or instead of a built-in battery. Since people like to use a touch panel to input information to electronic devices, what is needed is an electronic apparatus using solar cells for generating power as well as receiving input.

### BRIEF DESCRIPTION OF THE DRAWINGS

The components in the drawings are not necessarily drawn to scale, the emphasis instead being placed upon clearly illustrating the principles of an electronic apparatus. Moreover, in the drawings, like reference numerals designate corresponding parts throughout the several views.

FIG. 1 is a block diagram of an electronic apparatus in accordance with an exemplary embodiment.

FIG. 2 is a schematic, front view of an electronic apparatus of FIG. 1.

FIG. 3A is a schematic diagram showing cross section of a solar power module of the electronic apparatus of FIG. 1, in accordance with an exemplary embodiment.

FIG. 3B is a schematic diagram in cross section of the solar power module of the electronic apparatus of FIG. 1, in accordance with another exemplary embodiment.

FIG. 4 is a circuit diagram of the electronic apparatus of FIG. 1.

### DETAILED DESCRIPTION

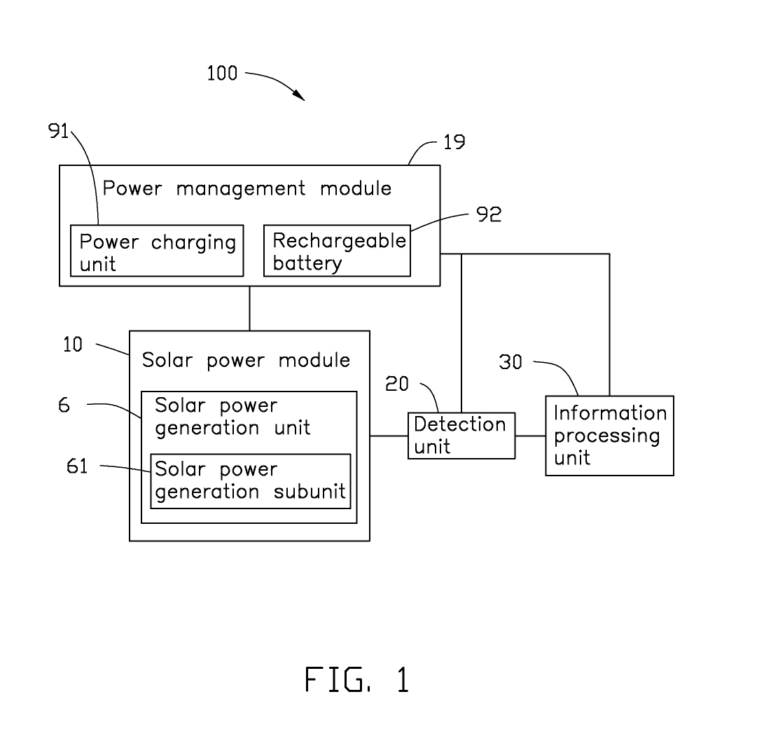

Referring to FIG. 1, an exemplary embodiment of an electronic apparatus 100 includes a solar power module 10, a power management module 19, a detection unit 20, and an information processing unit 30. The solar power module 10 includes a number of solar power generation units 6 and each of the solar power generation units 6 corresponds to a command of the electronic apparatus 100; each of the solar power generation units 6 further includes a number of solar power generation subunits 61. The power management module 19 includes a power charging unit 91 and a rechargeable battery 92, wherein the power generated from the solar power module 10 is stored in the rechargeable battery 92 through the power charging unit 91. The detection unit 20 can detect variation in parameters of the electricity generated by the solar power generation units 6 in accordance with the light absorbed by the solar power subunit 61, and transmit a signal to the information processing unit 30. The information processing unit 30 generates commands corresponding to the variations. The solar power module 10 works in coordination with the power management module 19 to supply power, and cooperates with the detection unit 20 and the information processing unit 30 to input commands. In the present embodiment, the variations can be measured as voltage, current, or power.

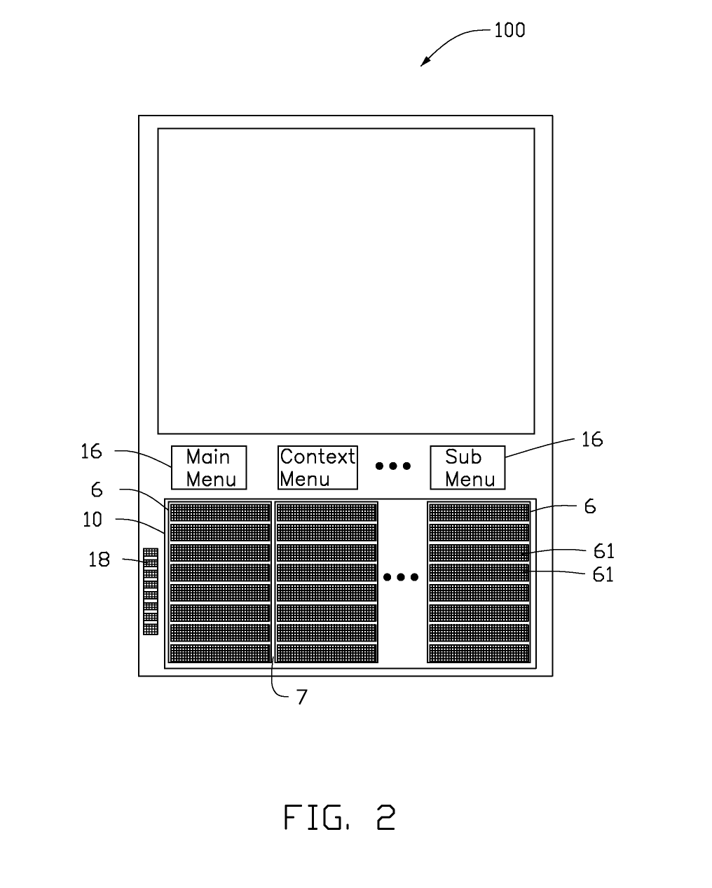

Referring to FIG. 2, a schematic front view of the electronic apparatus 100, the front of the electronic apparatus 100 includes the solar power module 10 for absorbing the photons in sunlight for power generation. The solar power module 10 includes a number of power generation units 6 which are separated with a number of separation units 7 in between each other, and each solar power generation unit 6 corresponds to a corresponding menu command of the electronic apparatus 100. For example, when the user wants to input a “main menu” command to enter the main menu of the electronic apparatus 100, the user can touch the “main menu” solar power generation unit 6 corresponding to the “main menu” command; the electrical parameter variation is detected by the detection unit 20 and the command is executed by the information processing unit 30. In the present embodiment, when the “main menu” solar power generation unit 6 is touched by the user, the voltage generated by the “main menu” solar power generation unit 6 drops and is about 54% lower than not being touched, but the “main menu” solar power generation unit 6, as well as other solar power generation units 6, can still generate electricity to the power management module 19. Therefore, the solar power module 10 can be used to input the command to the electronic apparatus 100 while generating power to the power management module 19.

The electronic apparatus 100 further includes a number of command indicators 16 and a number of input indicators 18, and each of the commands of the electronic apparatus 100 corresponds to one of the command indicators 16, one of the input indicators 18, and one of the solar power generation units 6. The command indicator 16 and the input indicator 18 are labeled with the corresponding command. For example, when a user wants to execute the “main menu” command of the electronic apparatus 100, the user finds the “main menu” command indicator 16 on the electronic apparatus 100 and touches the corresponding “main menu” solar power generation unit 6 which is in close proximity to the “main menu” command indicator 16. The electrical parameter of the “main menu” solar power generation subunit 61 varies due to shading of the “main menu” solar power generation unit 6 from light; the electrical parameter variation of the “main menu” solar power generation subunit 61 is then detected by the detection unit 20 and processed by the information processing unit 30 to execute the “main menu” command. In the present embodiment, the input indicators 18 are LED light, and the “main menu” input indicator 18 is lit when the “main menu” command is successfully executed by the electronic apparatus 100. In another embodiment, users can slide a finger through different solar power generation unit 6 to input a command, such as drawing a horizontal line, vertical line, diagonal line, or a clockwise circle on the solar power module 10 with a 3×3 grid of the solar power generation unit 6. The command corresponding to the gesture will be executed by the information processing unit 30.

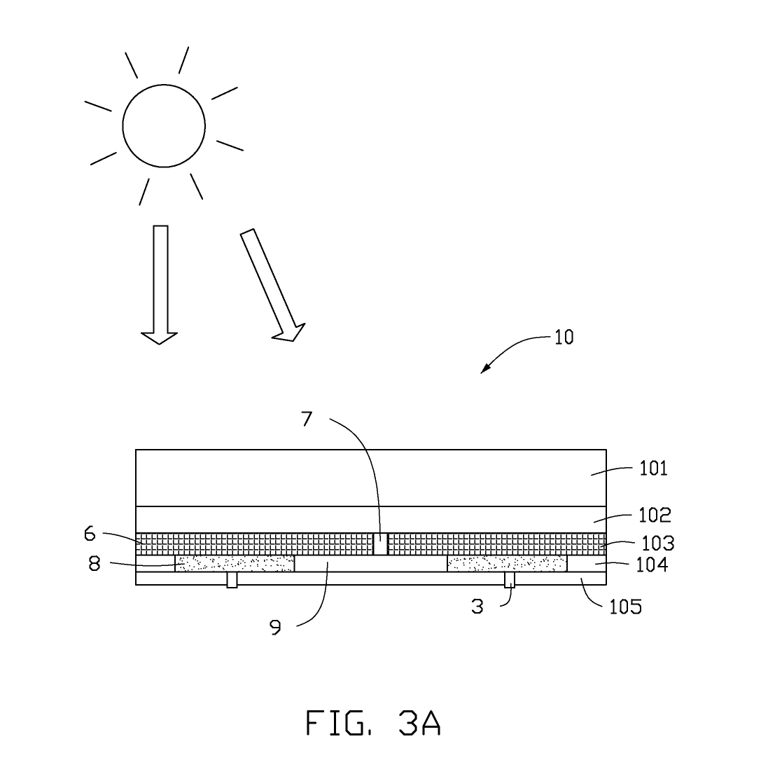

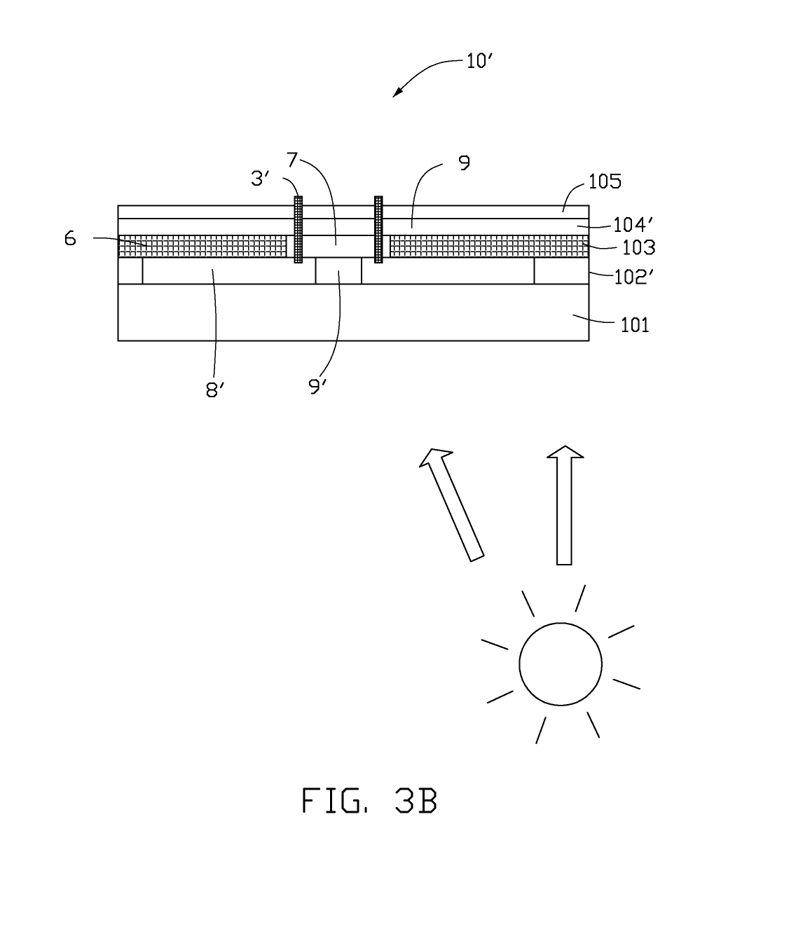

Referring to FIG. 3A, the solar power module 10 includes a transparent substrate 101, a solar power generation layer 103, a first electrode layer 102, a second electrode layer 104, and a protection layer 105. The solar power generation layer 103 is formed by a number of solar power generation units 6 insulated from each other by the separation units 7. In the present embodiment, the separation units 7 are made of insulating materials, and the composition of the solar power generation unit 6 includes but not limited to crystalline silicon, non-crystalline silicon, amorphous silicon, and organic materials.

The first electrode layer 102 and the second electrode layer 104 are electrically connected with the solar power generation unit 6. The solar power generation layer 103 is sandwiched between the first electrode layer 102 and the second electrode layer 104. In the present embodiment, the first electrode layer 102 is made of transparent conductive materials, like ITO films.

The first electrode layer 102 connects to one end of multiple solar power generation units 6, and act as a common electrode connected to ground to have the solar power generation units 6 grounded. The second electrode layer 104 includes a number of conductive electrodes 8 insulated from each other by insulation regions 9, and each conductive electrode 8 is connected to the other end of each solar power generation unit 6. The conductive electrodes 8 are further connected to the detection unit 20 and the power charging unit 91 through a conductive column 3. Therefore, the power generated by the solar power module 10 is stored in the rechargeable battery 92 through the power charging unit 91 while transmitting the electrical parameter variation to the detection unit 20. The protection layer 105 is used for binding the first electrode layer 102, the solar power generation layer 103, and the second electrode layer 104 to the transparent substrate 101.

Referring to FIG. 3B, in another embodiment, the first electrode layer 102′ includes a number of transparent conductive electrodes 8′ insulated from each other by transparent insulation regions 9′. One end of each conductive electrode 8′ is connected to one end of the solar power generation unit 6, and the other end of each conductive electrode 8′ is connected to the detection unit 20 and the power charging unit 91 through a conductive column 3′. The second electrode layer 104′ is connected with the other end of multiple solar power generation units 6 to form a common electrode connected to ground to allow multiple solar power generation units 6 to connect to ground.

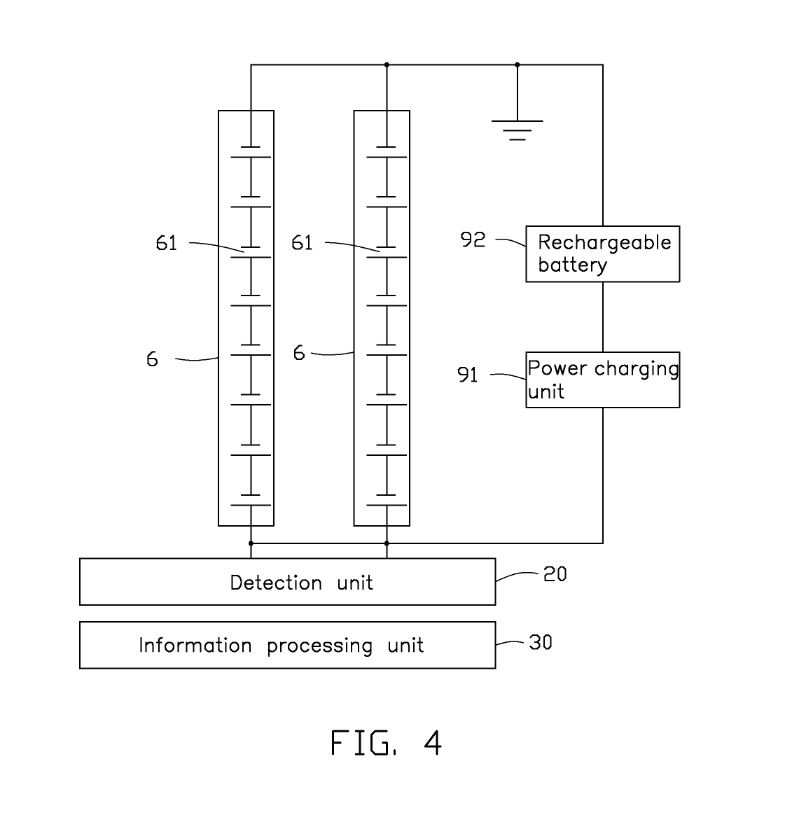

Referring to FIG. 4, the solar power generation unit 6 includes a number of solar power generation subunits 61 connected in series. When the light is blocked on one of the solar power generation subunit 61 due to touching on the solar power module 10, the electrical parameter of the solar power generation unit 6 will vary. The detection unit 20 then detects the variation of the electrical parameter of each solar power generation unit 6 and transmits a detection signal to the information processing unit 30, and the information processing unit 30 executes the command corresponding to the solar power unit 6. The solar power generation unit 6 is also connected to the power charging unit 91 to charge the rechargeable battery 92. In the present embodiment, the solar power generation subunit 61 is a photodiode which can generate a power of about 0.5V. Each of the solar power generation units 6 includes eight solar power generation subunits 61 connected in series, so the total output voltage of the solar power generation unit 6 is about 4V. In another embodiment, whole or part of the solar power generation units 61 can be connected in parallel to form the solar power generation unit 6.

In the present embodiment, the area of each solar power generation unit 6 is larger than a fingertip, and the area of each solar power generation subunit 61 is equal or smaller to the fingertip to ensure the accuracy of touch events detected on the solar power module 10.

Although the present disclosure has been specifically described on the basis of the exemplary embodiment thereof, the disclosure is not to be construed as being limited thereto. Various changes or modifications may be made to the embodiment without departing from the scope and spirit of the disclosure.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A solar power module, comprising:
a solar power generation layer for receiving photons, wherein the solar power generation layer comprises a plurality of solar power generation units;
a first electrode layer connected with the solar power generation layer; and
a second electrode layer connected with the solar power generation layer, wherein the second electrode layer comprises a plurality of conductive electrodes, and each conductive electrode is connected with one of the solar power generation unit; the conductive electrode transmits an electrical parameter variation of the corresponding solar power generation unit to a detection unit to transform the electrical parameter variation into corresponding input command.

2. The solar power module as claimed in claim 1, wherein the first electrode layer is connected to an end of each solar power generation unit and is grounded; the second electrode layer transfers power generated by the solar power generation unit to a power management module through the conductive electrode.

3. The solar power module as claimed in claim 2, wherein the solar power module further comprises a protection layer connected with the second electrode layer; the protection layer comprises a plurality of conductive column, and each conductive column is connected with the conductive electrode; through the conductive electrode and the conductive column, the power is transferred to the power management module, and the electrical parameter variation is transferred to the detection unit.

4. The solar power module as claimed in claim 2, wherein the power management module comprises a power charging unit and a rechargeable battery; the second electrode layer transfers the power to the power charging unit, and the power charging unit charges the rechargeable battery.

5. The solar power module as claimed in claim 1, wherein the solar power generation units are insulated from each other by a plurality of separation units.

6. The solar power module as claimed in claim 1, wherein the solar power generation layer is sandwiched between the first electrode layer and the second electrode layer.

7. The solar power module as claimed in claim 1, wherein the electrical parameter variation is voltage.

8. The solar power module as claimed in claim 1, wherein the solar power module further comprises a transparent substrate connected with the first electrode layer for protecting the first electrode layer.

9. The solar power module as claimed in claim 1, wherein the detection unit generates a detection signal corresponding to the electrical parameter variation; the detection signal is transferred to an information processing unit which generates the input command.

10. The solar power module as claimed in claim 1, wherein each of the solar power generation unit comprises a plurality of solar power generation subunits connected between each other.

11. The solar power module as claimed in claim 10, wherein the solar power generation subunits are photodiodes.
